(19) United States
(12) Patent Application Publication
(10) Pub. No.: US 2024/0105678 A1
(43) Pub. Date: Mar. 28, 2024

(54) CHIP PACKAGE, METHOD OF FORMING A CHIP PACKAGE, AND CHIP SYSTEM

(71) Applicant: Infineon Technologies AG, Neubiberg (DE)

(72) Inventors: Thorsten MEYER, Regensburg (DE); Angela KESSLER, Sinzing (DE); Thorsten SCHARF, Kareth (DE)

(73) Assignee: Infineon Technologies AG, Neubiberg (DE)

(21) Appl. No.: 18/243,231

(22) Filed: Sep. 7, 2023

(30) Foreign Application Priority Data
Sep. 28, 2022 (DE) 10 2022 124 935.2

(51) Int. Cl. H01L 25/065; H01L 21/56; H01L 23/00; H01L 23/31; H01L 23/495; H01L 25/00

(52) U.S. Cl. CPC H01L 25/0655; H01L 21/565; H01L 21/568; H01L 23/3107; H01L 23/49541; H01L 23/49568; H01L 24/19; H01L 24/24; H01L 25/50; H01L 2224/19; H01L 2224/24137

(57) ABSTRACT

A chip package is provided. The chip package includes an electrically conductive carrier structure, a first power chip on the carrier structure having a control contact pad and a second power chip on the carrier structure having a control contact pad. The first and second power chips are arranged with their respective control contact pad facing a redistribution layer. A logic chip is arranged with a logic contact pad facing a redistribution layer, wherein the redistribution layer connects the logic contact pad with the respective control pads of the power chips.

### CROSS-REFERENCE TO RELATED APPLICATION

This Utility patent application claims priority to German Patent Application No. 10 2022 124 935.2 filed Sep. 28, 2022, which is incorporated herein by reference.

### TECHNICAL FIELD

Various embodiments relate generally to a chip package, to a method of forming a chip package, and to a chip system.

### BACKGROUND

A power stage package construction typically combines power chips (which may for example form a high side and/or a low side, respectively, of the power stage package) and a logic chip. An advantage of such a construction may be that a high peak efficiency and a high load efficiency may be reached. Such a construction may for example be supported by a package that includes a redistribution layer, in order to minimize parasitics and to allow for the necessary tight pitches that are typically required by the logic chip interconnection. Such tight interconnection pitches usually cannot be realized by chip embedding technologies as presently used in the art.

### SUMMARY

A chip package is provided. The chip package includes an electrically conductive carrier structure, a first power chip arranged on the carrier structure, wherein the first power chip includes a first side with a control contact pad and a controlled contact pad of a first type, a second side opposite the first side, the second side comprising a controlled contact pad of a second type, and a control structure for controlling a current between the controlled contact pads, wherein the control contact pad is electrically connected to the control structure by a via, a second power chip arranged on the carrier structure, wherein the second power chip includes a first side with a control contact pad and a controlled contact pad of a second type, a second side opposite the first side, the second side comprising a controlled contact pad of a first type, and a control structure for controlling a current between the controlled contact pads of the second power chip, wherein the control contact pad is electrically connected to the control structure, a logic chip with a logic contact pad, a redistribution layer, and a mold material at least partially encapsulating the carrier structure, the first power chip, the second power chip, and the logic chip, wherein the first power chip and the second power chip are arranged with their respective control contact pad facing the redistribution layer, and the logic chip is arranged with the logic contact pad facing the redistribution layer, and wherein the redistribution layer electrically connects the logic contact pad with the respective control pads of the first power chip and of the second power chip.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

each of FIGS. 1A, 1B, and 1C shows a schematic view of a chip package in accordance with various embodiments;

FIGS. 2A to 2K show schematic illustrations of sequential processes of a method of forming a chip package in accordance with various embodiments;

each of FIGS. 3A and 3B shows a schematic view of a chip system in accordance with various embodiments; and

FIG. 4 shows a flow diagram of a method of forming a chip package in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

Recent semiconductor chip generations make it possible, by using through-silicon vias (TSVs), to arrange any chip pad on any main side of an electronic chip. For example, all pads may be arranged on the same side of the chip, or an arbitrary subset of pads may be arranged on a selected side of the chip. For example, rather than providing, as usual, a drain pad and a gate pad of a transistor chip on one side, and a source pad on the opposite side, the source pad and the gate pad may be arranged on one side, and the drain pad on the opposite side.

In various embodiments, embedded wafer level ball grid array (eWLB) technology is used for integrating at least one chip having a through-silicon via (also referred to as TSV chip) and at least one chip without a through-silicon via (also referred to as non-TSV chip) into a single chip package. Combining the TSV chip and the non-TSV chip makes it possible to arrange respective control pads (e. g., gate pads) of both chips and different types of controlled pads (e. g., a source pad of the TSV chip and a drain pad of the non-TSV chip) on a common plane, and thereby allows to electrically connect and/or contact the TSV chip and the non-TSV chip by using only planar connection structures for connecting the chips (in other words, no through-package connections are necessary).

For example, a redistribution layer may be formed over and electrically conductively connected to the control pads of both chips. A logic chip for driving the TSV chip and the non-TSV chip may additionally be included in the chip package. Its contact pads (in particular, its logic contact pad that may be used for controlling the TSV chip and the non-TSV chip) may be arranged on a common plane with the (control) pads of the TSV chip and the non-TSV chip, and may be electrically connected to the redistribution layer. The control pads and the controlled pads of the TSV chip and the non-TSV chip may be electrically connected to the redistribution layer.

The TSV chip and the non-TSV chip (and, optionally, the logic chip) may form a common circuit, for example forming a half bridge, a full bridge, a power module, a converter, or any other power application.

In various embodiments, the chip package may form a power stage package that combines power chips (high side (HS)/low side (LS)) and a logic chip. An advantage of of the chip package is that a high peak efficiency and a high load efficiency may be achieved by forming the chip package with a redistribution layer, in order to minimize parasitics and to allow for the necessary tight pitches for the logic chip interconnection. Logic components typically require very tight interconnection pitches, which are typically essentially impossible to achieve using classic chip embedding technologies. Since in TSV chips, chip pads may be distributed as desired over the sides of the chip due to the use of the TSVs, the well-known eWLB technology may offer many advantages for power stages that are formed by eWLB technology using TSV chips.

In various embodiments, a power stage arrangement, for example a chip package or a chip system that may include the chip package, with pure vertical current flow in the package may be provided. The chip package or chip system may include a TSV chip (e. g., a power chip) with its chip pads on an arbitrary side and at least one logic chip. The chips may be embedded in a mold compound. An electrically conductive carrier (e. g., thick copper) may be provided as a carrier (e. g., underneath) the power chips (HS, LS), and a redistribution layer may be provided for interconnection of the chips.

In various embodiments, an eWLB process flow may be used for forming a chip package, for example a power stage. This is possible without via technology in eWLB, since the TSV chip allows all contacts (or rather: arbitrary contacts) to be together on one side of the chip.

The eWLB based process technology may offer advantages compared to other embedding technologies. For example, the chip(s) may be embedded in a well-known mold compound instead of a laminate material. Ion contents, isolation properties, and process requirements of mold compounds are typically well understood. Also, CTE adaptations, different filler cuts and other options allow adaptions that may be required in some embodiments.

In various embodiments, the redistribution layer may be applied on a top side of a reconstituted wafer that may have been formed by the embedding process. This arrangement may allow to align the redistribution layer and the logic die optically. Therefore, a contacting of small pad dimensions in tight pitches may be made possible, as opposed to standard laser based via technology of classical chip embedding technologies, which may require much larger pads with larger pitches, which may cause additional costs.

In various embodiments, a thick metal carrier, e. g., a copper sheet, may be provided on a backside of the reconsituted wafer and in electrical and thermal contact with the (e. g., power) chips. This may allow for a high thermal performance and also top side cooling/double side cooling, and for a pure vertical current flow.

Each of FIGS. 1A, 1B, and 1C shows a schematic view of a chip package 100 in accordance with various embodiments.

The chip package 100 includes an electrically conductive carrier structure 102. The electrically conductive carrier structure 102 may for example include or consist of copper or a copper alloy, for example a thick copper layer or layer structure like a layer stack, for example with a thickness in a range from about 100 μm to about 300 μm, for example from about 150 μm to about 250 μm. The carrier structure 102 may have a high electrical and thermal conductivity, for example an electrical and thermal conductivity similar to that of copper. The high electrical conductivity may ensure that large vertical currents through the carrier structure 102 may be achieved. The high thermal conductivity may ensure that heat generated in the chip package 100 may be easily transported to an outside of the chip package 100.

The chip package 100 further includes a first power chip 104 arranged on the carrier structure 102, for example a power transistor, for example a (power) MOSFET, or any other suitable electronic power device, for example a power diode.

The first power chip 104 includes a first side 104S1 with a control contact pad 104_C and a controlled contact pad 104_1 of a first type, a second side 104S2 opposite the first side 104S1, the second side 104S2 comprising a controlled contact pad 104_2 of a second type, and a control structure (for example a gate and/or a switching transistor) for controlling a current between the controlled contact pads 104_1, 104_2, wherein the control contact pad 104_C is electrically connected to the control structure by a via 120 (for example a through silicon via TSV). In this document, the term “via” is used to describe a vertical electrical connection through the silicon, wherein the vertical electrical connection is insulated from the bulk material. The known TSV is an embodiment, but the via is not limited to this.

In FIG. 1A, a zoomed-in view of the via 120 region is shown in the bottom drawing. The via 120 may in various embodiments be formed by an electrically conductive material, for example polysilicon. At an interface between the via 120 and bulk material 104B of the first power chip 104, insulating material 118 may be arranged, for example silicon oxide or any other suitable material, for electrically insulating the via from sensitive semiconductor structures, e. g. transistor structures, that may be formed in the semiconductor bulk material 104B.

The controlled contact pad 104_1 of the first type may for example be a source contact pad, and the controlled contact pad 104_2 of the second type may for example be a drain contact pad.

The chip package 100 further includes a second power chip 106 arranged on the carrier structure 102, for example a power transistor, for example a (power) MOSFET, or any other suitable electronic power device, for example a power diode.

The second power chip 106 includes a first side 106S1 with a control contact pad 106_C and a controlled contact pad 106_2 of a second type, a second side 106S2 opposite the first side 106S1, the second side 106S2 comprising a controlled contact pad 106_1 of a first type, and a control structure (for example a gate and/or a switching transistor) for controlling a current between the controlled contact pads 106_1, 106_2 of the second power chip 106, wherein the control contact pad 106_C is electrically connected to the control structure.

The controlled contact pad 106_1 of the first type may for example be a source contact pad, and the controlled contact pad 106_2 of the second type may for example be a drain contact pad.

This means that the second power chip 106 may, for example, be configured like most power chips that are presently used in the art and that include a control contact pad and two controlled contact pads of, e. g., a transistor, namely that the drain contact pad and the control contact pad are arranged on the same side of the chip package 100.

The first power chip 104, on the other hand, may for example be configured differently, in that the TSV may be used for arranging the control contact pad 104_C on the same side as the source contact pad.

As described above, this allows to arrange the two control contact pads 104_C, 106_C, one of the controlled contact pads of the first type, for example the (e. g., source) contact pad 104_1 of the first power chip 104, and one of the controlled contact pads of the second type, for example the (e. g., drain) contact pad 106_2 of the second power chip 106, in a common plane.

The chip package 100 further includes a logic chip 108 with a logic contact pad 108_C.

The logic chip 108 may for example be or include any kind of driver chip or control chip that is regularly used for providing control in a power chip package.

The chip package 100 further includes a redistribution layer (RDL) 114. The redistribution layer 114 may include or consist of a structured electrically conductive (e. g., metal) layer or layer structure, e. g. a layer stack, for example including or consisting of copper or a copper alloy or other suitable metal as used in the art for redistribution layers.

The chip package 100 further includes a mold material 110 at least partially encapsulating the carrier structure 102, the first power chip 104, the second power chip 106, and the logic chip 108. The mold material 110 may be or include a suitable mold material as used in the art as an encapsulant in power chip packages. The mold material 110 may for example be selected or adjusted (e. g. by suitably selected additives) regarding its thermal conductivity, its coefficient of thermal expansion (CTE), its mechanical properties, etc.

As briefly outlined above, in the chip package 100, the first power chip 104 and the second power chip 106 may be arranged with their respective control contact pad 104_C, 106_C facing the redistribution layer 112, and the logic chip 108 may be arranged with the logic contact pad 108_C facing the redistribution layer 112. The redistribution layer 112 electrically connects the logic contact pad 108_C with the respective control contact pads 104_C, 106_C of the first power chip 104 and of the second power chip 106.

The control contact pads 104_C, 106_C and the controlled contact pads 104_1, 106_2, of the first power chip 104 and the second power chip 106, respectively, which are arranged facing away from the carrier 102, and the logic contact pad 108_C may be electrically connected to the redistribution layer 112.

The above described configuration may allow for a total thickness of a stack of the first power chip 104 and the carrier structure 102 to be larger than a thickness of the logic chip 108, and, respectively, a total thickness of a stack of the second power chip 106 and the carrier structure 102 to be larger than a thickness of the logic chip 108.

This may easily make it possible to obtain a chip package 100, in which the carrier structure 102 may be exposed at first main side of the chip package 100, whereas the logic chip 108 may be covered by the mold 110 on the first main side. This may allow for excellent heat management of the power chips 104, 106, while at the same time providing electrical insulation over a second side 108S2 of the logic chip 108.

The carrier structure 102 may be integrally formed as a carrier for both power chips 104, 106, e. g., having an L-shape, or may include separate portions for carrying the first power chip 104 and the second power chip 106, respectively. The carrier structure 102 may include an electrically conductive first portion contacting the first power chip 104 and an electrically conductive second portion contacting the second power chip 106, and may optionally include an electrically conductive connecting portion connecting the first portion and the second portion.

In various embodiments, the electrically conductive carrier structure 102 may include an extension overlapping the logic chip 108, wherein the extension is electrically isolated from the logic chip by the mold material 112.

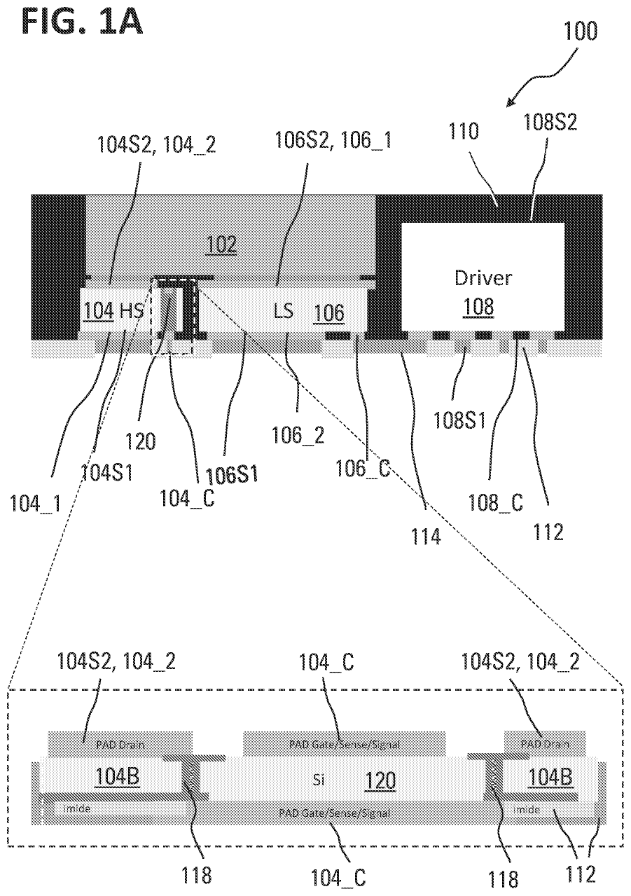

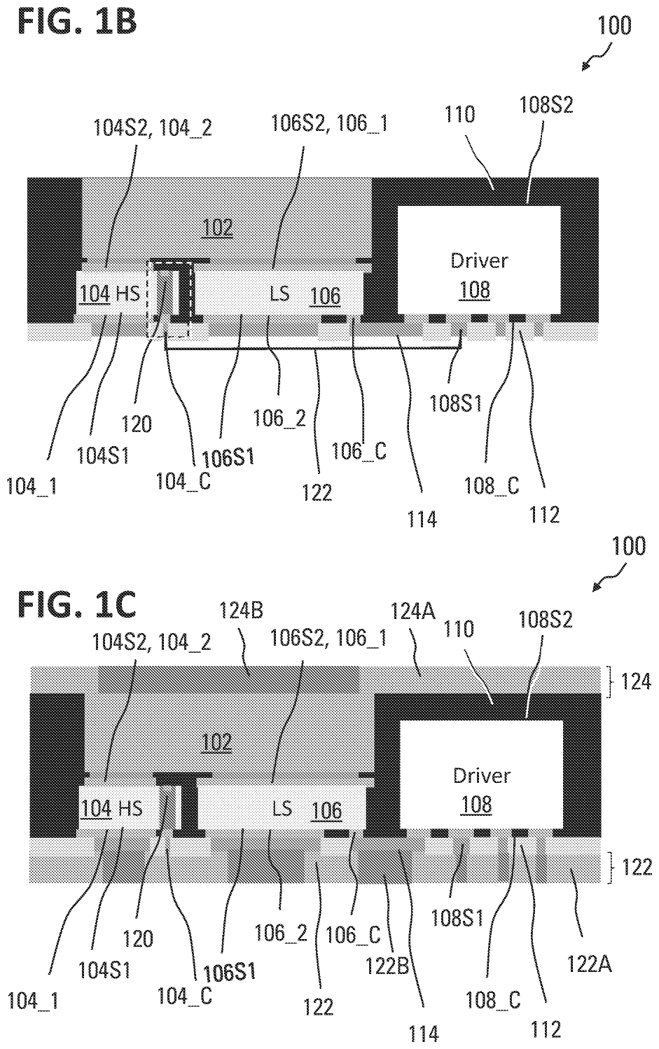

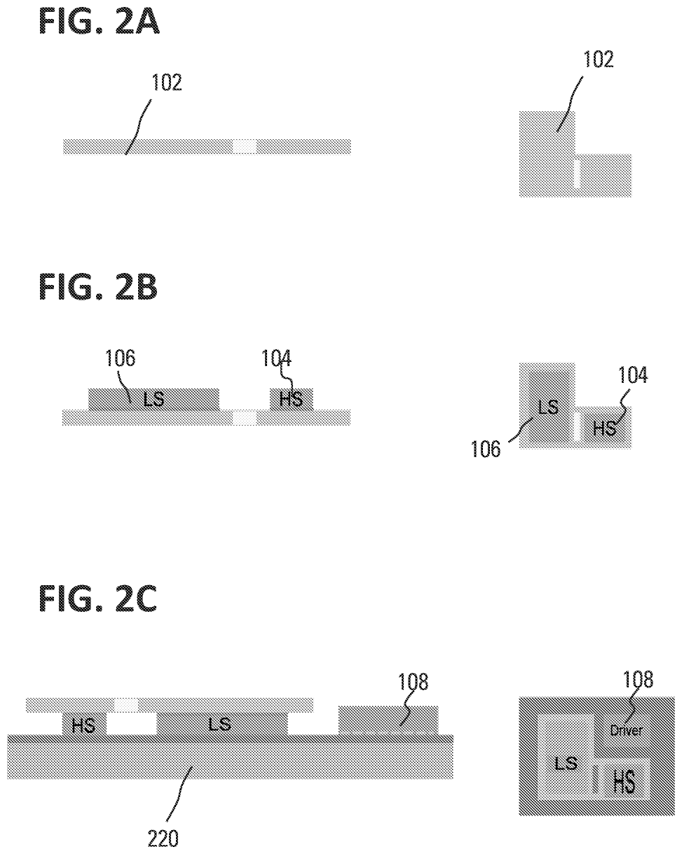

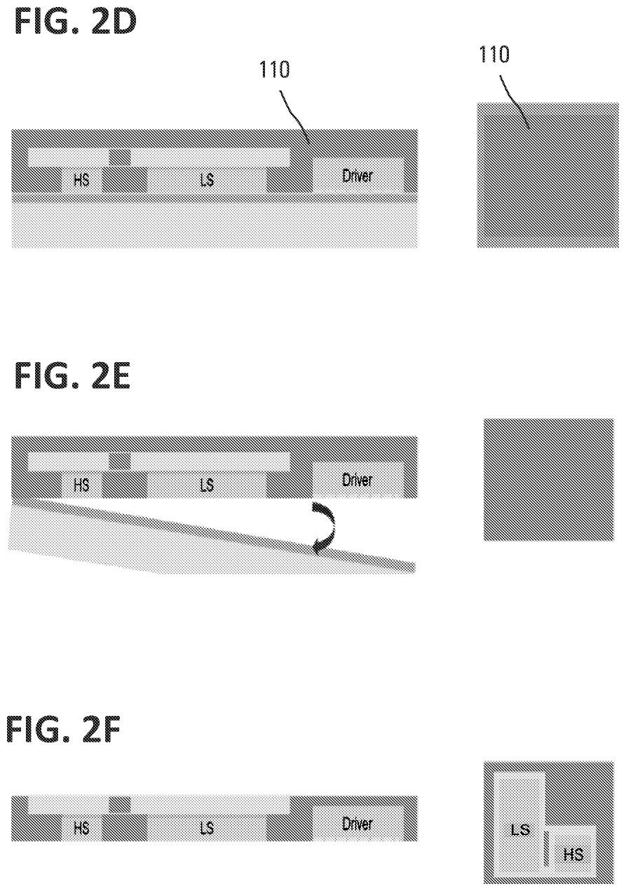

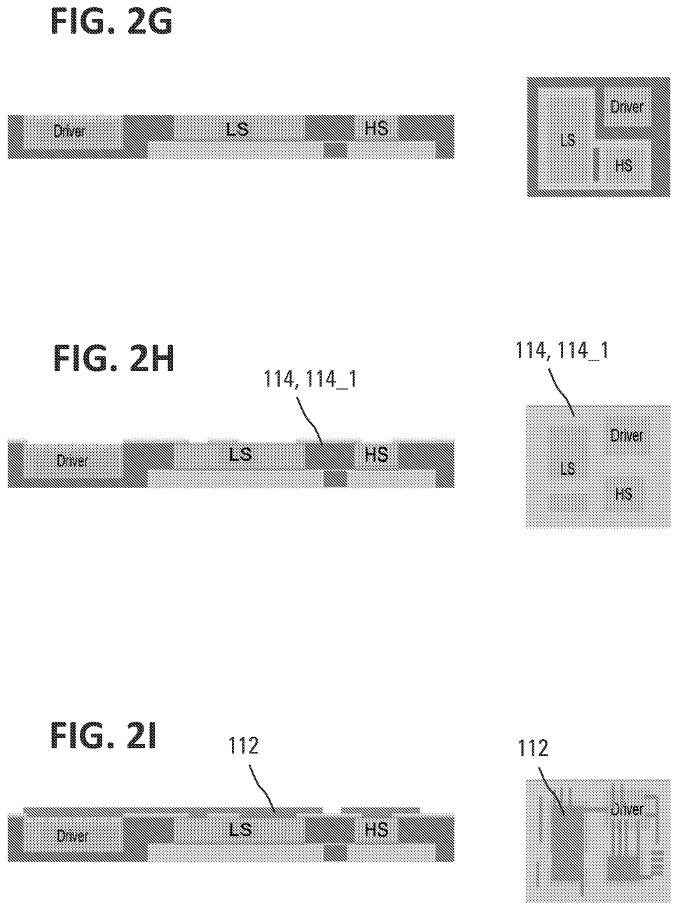

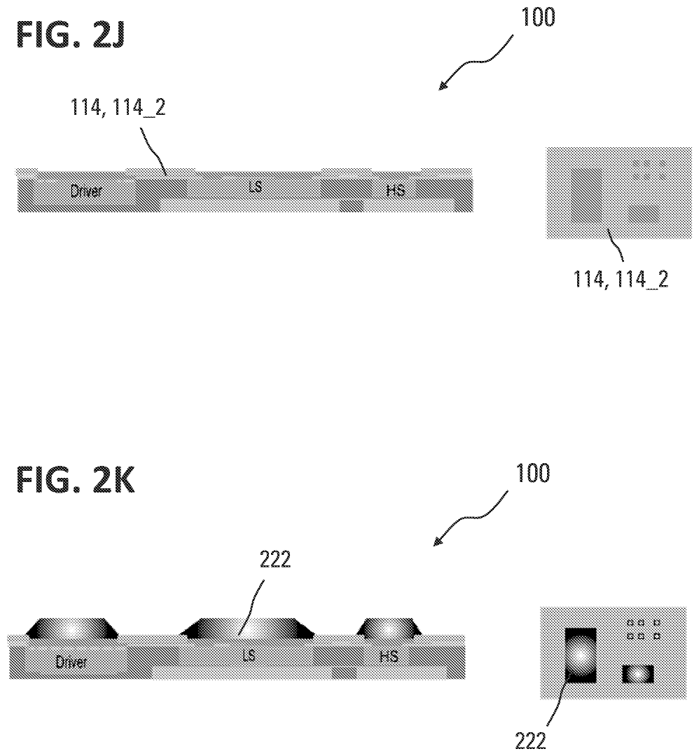

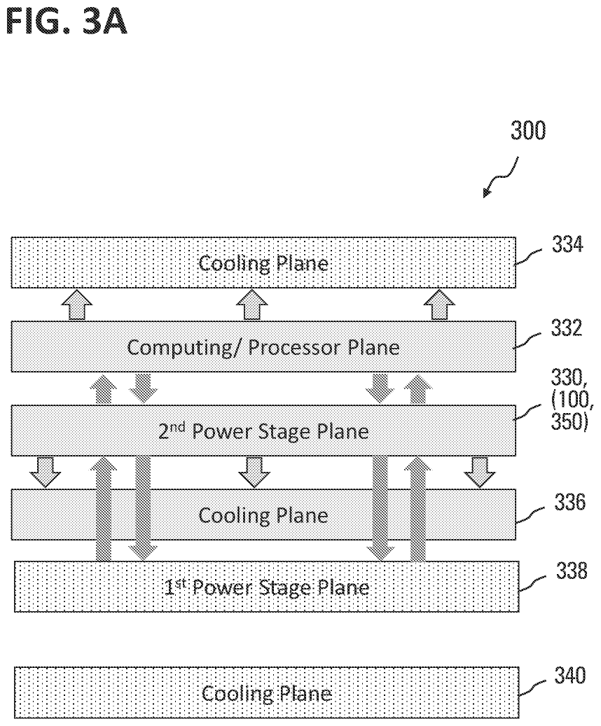

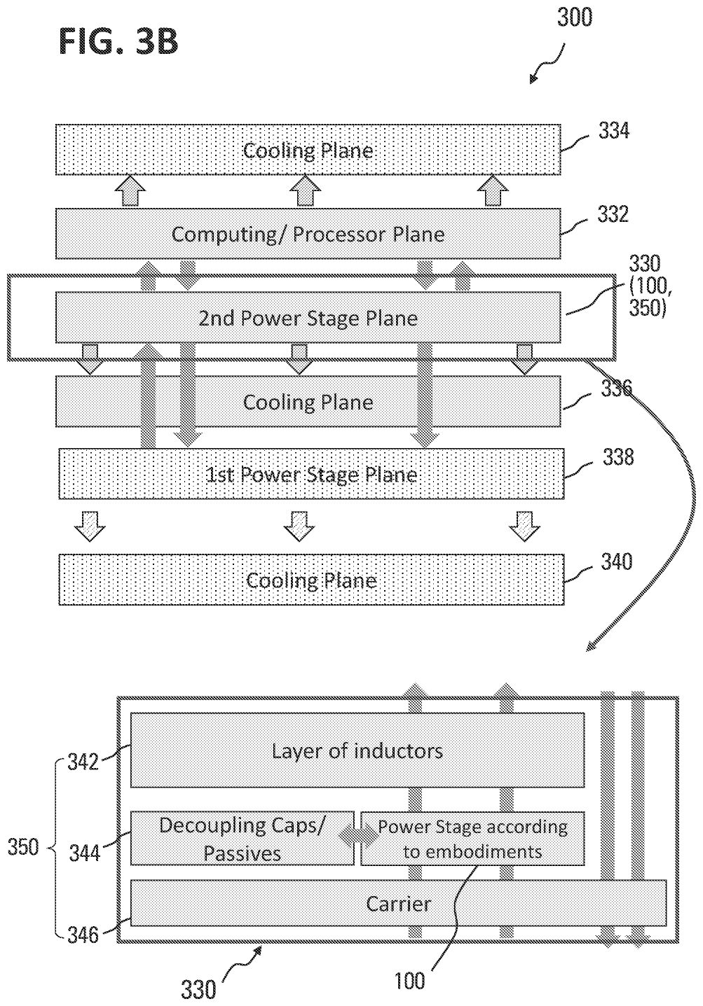

FIGS. 2A to 2K show schematic illustrations of sequential processes of a method of forming a chip package in accordance with various embodiments. In each of FIGS. 2A to 2K, a schematic cross-sectional view is shown on the left, and a schematic top view is shown on the right. The cross-sectional view is to be understood as schematic in a sense that no specific cross-sectional line is followed through the chip package, but rather, that a vertical layer structure and relative vertical positioning of the structures is illustrated. In FIGS. 2A to 2K, to avoid crowding, reference numbers may only be shown when an element is first arranged, and possibly not all reference numbers that may be used in the following description may be found in FIGS. 2A to 2K. If necessary, please consult the other figures, for example FIG. 1.

As shown in an illustrative exemplary fashion in FIG. 2A, the method of forming a chip package may start with the carrier structure 102, for example a copper sheet, which may contain openings at certain positions in order to allow an easier mold compound flow during molding later. The carrier structure 102 may for example haf an L-shape.

As shown in an illustrative exemplary fashion in FIG. 2B, the first power chip 104 (low side (LS)) and the second power chip 106 (high side (HS) may be attached to the carrier structure 102 in such a way that their respective control contact pads 104_C, 106_C (and the respective controlled contact pads 104_1, 106_2 arranged on the same sides of the respective chip as the control contact pads 104_C, 106C) face away from the carrier structure 102. This may for example be done by gluing, soldering, diffusion soldering or sintering.

As shown in an illustrative exemplary fashion in FIG. 2C, this pre-fabricated arrangement is then flipped and placed onto a temporary carrier 220. The temporary carrier 220 may for example include an adhesive tape on an eWLB mold carrier. The contact pads 104_C, 106_C, 104_1, 106_2 may face the temporary carrier 220, and the carrier 102 may face away from the temporary carrier 220.

The logic chip 108, and optionally further driver/controller logic components, may be attached to the temporary carrier 220, also with contact pads, e. g. the logic contact pad 108_C, facing towards the temporary carrier 220.

The overall height of the logic chip may be lower than the overall height of the stack including the carrier structure 102 and the power chip 104 or 106, respectively.

As shown in an illustrative exemplary fashion in FIG. 2D, the chips 104, 106, 108 my be over-molded on the temporary carrier 220. This may for example be achieved with a granular, a liquid, or a sheet type of mold compound. Either standard compression molding or a film assisted molding approach may for example be used for this. The openings in the carrier structure 102 may support the mold fill underneath the carrier structure 102. If required, a smaller filler cut, like for molded underfill solutions, may need to be used.

In standard eWLB compression molding, this may lead to a situation as shown in FIGS. 2D and 2E, in which a layer of mold compound 110 covers the carrier structure 102 as well as the logic chip 108. In this case, a process of removing the temporary carrier 220 according to the standard eWLB process (see FIG. 2E), followed by a grinding step, which exposes the carrier structure 102 from the mold compound 110, but not the logic die 108, may be applied. Also, a warpage adjust process may be performed as part of this process sequence.

In a case where film assisted molding is used for applying the mold compound 110, only a cleaning process of the surface of the carrier structure 102 (and the removal of the temporary carrier 220) may be required.

The structure thus formed may also be referred to as a reconstituted wafer, which is is subsequently flipped again (see FIG. 2G).

A dielectric layer 114, 114_1 (see FIG. 2H) may subsequently be applied. The dielectric layer 114, 114_1 may for example be printed, spinned, laminated or similar and, if required, may be structured, for example using photolithography.

A redistribution layer 112 (see FIG. 2I) may subsequently be applied. The RDL may for example be applied using semi-additive processes in thin-film technology, e. g. by sputtering and electroplating, or any other suitable application method used in the art.

A thickness of the redistribution layer 112 may be adapted to the needs in a certain range of layer thickness, wherein a metallization thickness of standard chip embedding technologies may be reached.

As shown in FIG. 2J, optionally, a solder stop layer 114_2, which may be a dielectric, thus forming a further portion of the dielectric layer 114, may be applied over or (e. g., directly) on the dielectric layer 114_1 and/or portions of the redistribution layer 112.

Finally, as shown in FIG. 2K, a solder depot 222, e. g., a solder paste, or a noble pad finish may be applied.

In various embodiments, different fan-out wafer level packaging technologies may be used. The above described eWLB (RDL last) is one option, but also RDL first fan-out technology may optionally be used.

In addition to the power chips 104, 106 and the logic chip(s) 108 described above, further power chips, logic chips (e. g., configured as a controller) and/or passive components (e. g., capacitors, resistors, etc.) may be embedded in the mold compound 110 and may be connected using the RDL layer(s) 112, and an application of land side capacitors may be possible, and optionally a provision of a via from the carrier structure 102 through the mold compound 110 for connecting, e. g., a passive component like a capacitor. A copper block, via bar, laser drilled via or an etched copper structure may for example be used for forming the electrically conductive connection.

In various embodiments, rather than applying the solder depot 222, the chip package may be used as inlay with pure vertical current flow and may be embedded in a PCB (e. g., as a so-called Schweizer Inlay Embedding).

The Vswitch connection maybe connected at the low side and can be connected with the Boot-Capacitor by the RDL. Alternatively, the Boot-capacitor can be directly attached to the copper substrate in order to keep distances low. A Via connection from the copper substrate through the mold compound is also possible in order to connect the Boot-capacitor. A copper block, via bar, laser drilled via or an etched copper structure can be used.

Each of FIGS. 3A and 3B shows a schematic view of a chip system 300 in accordance with various embodiments. The chip system 300 shown in FIG. 3B is essentially the same as shown in FIG. 3A, but with an additional more detailed illustration of one of the components

The chip system 300 may include at least one chip package 100 in accordance with various embodiments, for example as described above in context with the chip package of FIG. 1 and/or as formed by the method illustrated in FIGS. 2A to 2K.

The chip system 300 may further include at least one further component of a group of further components, the group consisting of a processor 332, a controller 338, a cooling structure 334, 340, and a power source.

In the exemplary chip system 300 of FIG. 3A and/or FIG. 3B, the chip package 100 is part of component 330, in the figures also labelled as “2^{nd} power stage plane”.

As shown in FIG. 3B, the component 330 may include, besides the chip package 100, passive components, e. g. capacitors 334, inductors 342, for example arranged as a layer of inductors, and another carrier 346.

The chip system 300 may in various embodiments be configured as a half bridge, a converter, or a full bridge.

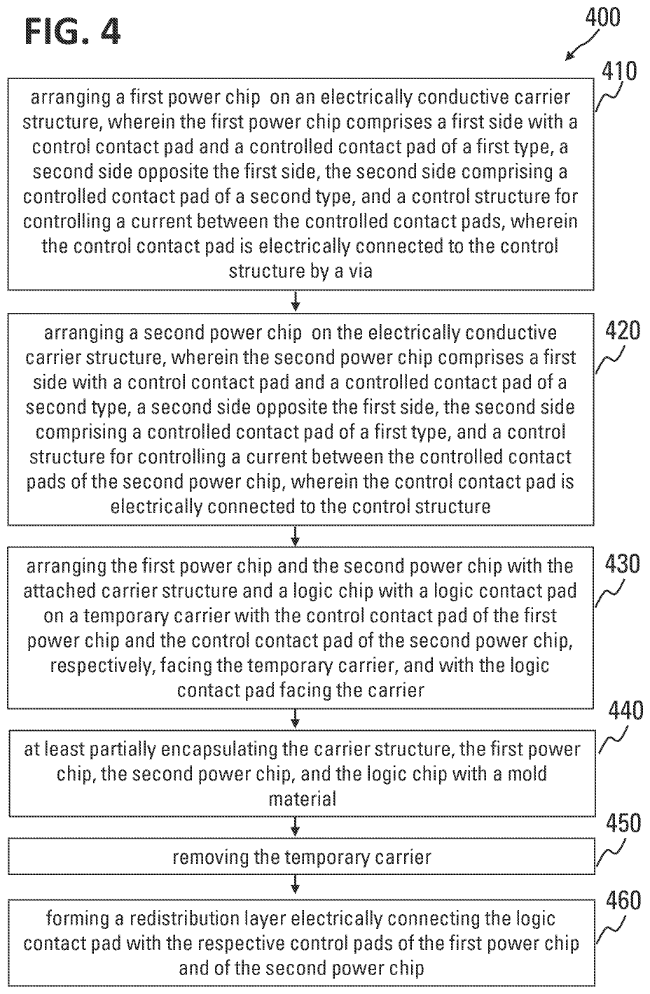

FIG. 4 shows a flow diagram 400 of a method of forming a chip package in accordance with various embodiments.

The method may include arranging a first power chip on an electrically conductive carrier structure, wherein the first power chip includes a first side with a control contact pad and a controlled contact pad of a first type, a second side opposite the first side, the second side comprising a controlled contact pad of a second type, and a control structure for controlling a current between the controlled contact pads, wherein the control contact pad is electrically connected to the control structure by a via (410), arranging a second power chip on the electrically conductive carrier structure, wherein the second power chip includes a first side with a control contact pad and a controlled contact pad of a second type, a second side opposite the first side, the second side comprising a controlled contact pad of a first type, and a control structure for controlling a current between the controlled contact pads of the second power chip, wherein the control contact pad is electrically connected to the control structure (420), arranging the first power chip and the second power chip with the attached carrier structure and a logic chip with a logic contact pad on a temporary carrier with the control contact pad of the first power chip and the control contact pad of the second power chip, respectively, facing the temporary carrier, and with the logic contact pad facing the carrier (430), at least partially encapsulating the carrier structure, the first power chip, the second power chip, and the logic chip with a mold material (440), removing the temporary carrier (450), and forming a redistribution layer electrically connecting the logic contact pad with the respective control pads of the first power chip and of the second power chip (460).

Various examples will be illustrated in the following:

Example 1 is a chip package. The chip package includes an electrically conductive carrier structure, a first power chip arranged on the carrier structure, wherein the first power chip includes a first side with a control contact pad and a controlled contact pad of a first type, a second side opposite the first side, the second side comprising a controlled contact pad of a second type, and a control structure for controlling a current between the controlled contact pads, wherein the control contact pad is electrically connected to the control structure by a via, a second power chip arranged on the carrier structure, wherein the second power chip includes a first side with a control contact pad and a controlled contact pad of a second type, a second side opposite the first side, the second side comprising a controlled contact pad of a first type, and a control structure for controlling a current between the controlled contact pads of the second power chip, wherein the control contact pad is electrically connected to the control structure, a logic chip with a logic contact pad, a redistribution layer, and a mold material at least partially encapsulating the carrier structure, the first power chip, the second power chip, and the logic chip, wherein the first power chip and the second power chip are arranged with their respective control contact pad facing the redistribution layer, and the logic chip is arranged with the logic contact pad facing the redistribution layer, and wherein the redistribution layer electrically connects the logic contact pad with the respective control pads of the first power chip and of the second power chip.

In Example 2, the subject-matter of Example 1 may optionally include that the carrier structure is exposed at first main side of the chip package, whereas the logic chip is covered by the mold on the first main side.

In Example 3, the subject-matter of Example 1 or 2 may optionally include that the controlled contact pad of the first type is a source contact pad, and the controlled contact pad of the second type is a drain contact pad.

In Example 4, the subject-matter of any of Examples 1 to 3 may optionally include that a total thickness of a stack of the first power chip and the carrier structure is larger than a thickness of the logic chip, and wherein a total thickness of a stack of the second power chip and the carrier structure is larger than a thickness of the logic chip.

In Example 5, the subject-matter of any of Examples 1 to 4 may optionally include that the carrier structure includes an electrically conductive first portion contacting the first power chip and an electrically conductive second portion contacting the second power chip, and optionally includes an electrically conductive connecting portion connecting the first portion and the second portion.

In Example 6, the subject-matter of any of Examples 1 to 5 may optionally include that the electrically conductive carrier structure has a thickness in a range from about 100 μm to about 300 μm.

In Example 7, the subject-matter of any of Examples 1 to 6 may optionally include that the electrically conductive carrier structure includes an extension overlapping the logic chip, wherein the extension is electrically isolated from the logic chip by the mold material.

In Example 8, the subject-matter of any of Examples 1 to 7 may optionally include that the electrically conductive carrier includes or consists of copper.

In Example 9, the subject-matter of any of Examples 1 to 8 may optionally include that the currents between the controlled pads of the first power chip and the second power chip, respectively, are vertical currents through the power chip and the chip package,

In Example 10, the subject-matter of any of Examples 1 to 9 may optionally include that the first power chip and the second power chip are connected in a half-bridge configuration.

Example 11 is a method of forming a chip package. The method may include arranging a first power chip on an electrically conductive carrier structure, wherein the first power chip includes a first side with a control contact pad and a controlled contact pad of a first type, a second side opposite the first side, the second side comprising a controlled contact pad of a second type, and a control structure for controlling a current between the controlled contact pads, wherein the control contact pad is electrically connected to the control structure by a via, arranging a second power chip on the electrically conductive carrier structure, wherein the second power chip includes a first side with a control contact pad and a controlled contact pad of a second type, a second side opposite the first side, the second side comprising a controlled contact pad of a first type, and a control structure for controlling a current between the controlled contact pads of the second power chip, wherein the control contact pad is electrically connected to the control structure, arranging the first power chip and the second power chip with the attached carrier structure and a logic chip with a logic contact pad on a temporary carrier with the control contact pad of the first power chip and the control contact pad of the second power chip, respectively, facing the temporary carrier, and with the logic contact pad facing the carrier, at least partially encapsulating the carrier structure, the first power chip, the second power chip, and the logic chip with a mold material, removing the temporary carrier, and forming a redistribution layer electrically connecting the logic contact pad with the respective control pads of the first power chip and of the second power chip.

In Example 12, the subject-matter of Example 11 may optionally include that the molding includes compression molding or film assisted molding.

In Example 13, the subject-matter of Example 12 may optionally include that the molding includes the compression molding, the method further comprising:

exposing the carrier structure at first main side of the chip package, while keeping the logic chip covered by the mold on the first main side, wherein the exposing optionally includes grinding.

In Example 14, the subject-matter of any of Examples 11 to 13 may optionally include that the controlled contact pad of the first type is a source contact pad, and the controlled contact pad of the second type is a drain contact pad.

In Example 15, the subject-matter of any of Examples 11 to 14 may optionally include that a total thickness of a stack of the first power chip and the carrier structure is larger than a thickness of the logic chip, and wherein a total thickness of a stack of the second power chip and the carrier structure is larger than a thickness of the logic chip.

In Example 16, the subject-matter of any of Examples 11 to 15 may optionally include that the carrier structure includes an electrically conductive first portion contacting the first power chip and an electrically conductive second portion contacting the second power chip, and optionally includes an electrically conductive connecting portion connecting the first portion and the second portion.

In Example 17, the subject-matter of any of Examples 11 to 16 may optionally include that the electrically conductive carrier structure has a thickness in a range from about 100 μm to about 300 μm.

In Example 18, the subject-matter of any of Examples 11 to 17 may optionally include that the electrically conductive carrier structure includes an extension overlapping the logic chip, wherein the extension is electrically isolated from the logic chip by the mold material.

In Example 19, the subject-matter of any of Examples 11 to 18 may optionally include that the electrically conductive carrier includes or consists of copper.

In Example 20, the subject-matter of any of Examples 11 to 19 may optionally include that the currents between the controlled pads of the first power chip and the second power chip, respectively, are vertical currents through the power chip and the chip package,

In Example 21, the subject-matter of any of Examples 11 to 20 may optionally include that the arranging the first power chip and/or the arranging the second power chip includes gluing, soldering, diffusion soldering and/or sintering.

In Example 22, the subject-matter of any of Examples 11 to 21 may further include, before the forming of the redistribution layer, arranging a structured dielectric layer over a side that is exposed by the removed temporary carrier.

In Example 23, the subject-matter of any of Examples 11 to 22 may optionally include that the forming the redistribution layer includes sputtering and/or electroplating.

In Example 24, the subject-matter of any of Examples 11 to 23 may optionally include that the first power chip and the second power chip are connected in a half-bridge configuration.

Example 25 is a chip system. The chip system may include at least one chip package of any of Examples 1 to 10, at least one further component of a group of further components, the group consisting of a processor, a controller, a cooling structure, and a power source, wherein the chip system is configured as a converter or a full bridge.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip package, comprising:
an electrically conductive carrier structure;
a first power chip arranged on the carrier structure, wherein the first power chip comprises a first side with a control contact pad and a controlled contact pad of a first type, a second side opposite the first side, the second side comprising a controlled contact pad of a second type, and a control structure for controlling a current between the controlled contact pads, wherein the control contact pad is electrically connected to the control structure by a via;
a second power chip arranged on the carrier structure, wherein the second power chip comprises a first side with a control contact pad and a controlled contact pad of a second type, a second side opposite the first side, the second side comprising a controlled contact pad of a first type, and a control structure for controlling a current between the controlled contact pads of the second power chip, wherein the control contact pad is electrically connected to the control structure;
a logic chip with a logic contact pad;
a redistribution layer; and
a mold material at least partially encapsulating the carrier structure, the first power chip, the second power chip, and the logic chip;
wherein the first power chip and the second power chip are arranged with their respective control contact pad facing the redistribution layer, and the logic chip is arranged with the logic contact pad facing the redistribution layer; and
wherein the redistribution layer electrically connects the logic contact pad with the respective control pads of the first power chip and of the second power chip.

2. The chip package of claim 1,
wherein the carrier structure is exposed at first main side of the chip package, whereas the logic chip is covered by the mold on the first main side.

3. The chip package of claim 1,
wherein the controlled contact pad of the first type is a source contact pad, and the controlled contact pad of the second type is a drain contact pad.

4. The chip package of claim 1,
wherein a total thickness of a stack of the first power chip and the carrier structure is larger than a thickness of the logic chip, and wherein a total thickness of a stack of the second power chip and the carrier structure is larger than a thickness of the logic chip.

5. The chip package of claim 1,
wherein the carrier structure comprises an electrically conductive first portion contacting the first power chip and an electrically conductive second portion contacting the second power chip, and optionally comprises an electrically conductive connecting portion connecting the first portion and the second portion.

6. The chip package of claim 1,
wherein the electrically conductive carrier structure has a thickness in a range from about 100 μm to about 300 μm.

7. The chip package of claim 1,
wherein the electrically conductive carrier structure comprises an extension overlapping the logic chip, wherein the extension is electrically isolated from the logic chip by the mold material.

8. The chip package of claim 1,
wherein the electrically conductive carrier comprises or consists of copper.

9. The chip package of claim 1,
wherein the currents between the controlled pads of the first power chip and the second power chip, respectively, are vertical currents through the power chip and the chip package;

10. The chip package of claim 1,
wherein the first power chip and the second power chip are connected in a half-bridge configuration.

11. A method of forming a chip package, the method comprising:
arranging a first power chip on an electrically conductive carrier structure, wherein the first power chip comprises a first side with a control contact pad and a controlled contact pad of a first type, a second side opposite the first side, the second side comprising a controlled contact pad of a second type, and a control structure for controlling a current between the controlled contact pads, wherein the control contact pad is electrically connected to the control structure by a via;
arranging a second power chip on the electrically conductive carrier structure, wherein the second power chip comprises a first side with a control contact pad and a controlled contact pad of a second type, a second side opposite the first side, the second side comprising a controlled contact pad of a first type, and a control structure for controlling a current between the controlled contact pads of the second power chip, wherein the control contact pad is electrically connected to the control structure;
arranging the first power chip and the second power chip with the attached carrier structure and a logic chip with a logic contact pad on a temporary carrier with the control contact pad of the first power chip and the control contact pad of the second power chip, respectively, facing the temporary carrier, and with the logic contact pad facing the carrier;
at least partially encapsulating the carrier structure, the first power chip, the second power chip, and the logic chip with a mold material;
removing the temporary carrier; and
forming a redistribution layer electrically connecting the logic contact pad with the respective control pads of the first power chip and of the second power chip.

12. The method of claim 11,
wherein the molding comprises compression molding or film assisted molding.

13. The method of claim 12,
wherein the molding comprises the compression molding, the method further comprising:
exposing the carrier structure at first main side of the chip package, while keeping the logic chip covered by the mold on the first main side, wherein the exposing optionally comprises grinding.

14. The method of claim 11,
wherein the controlled contact pad of the first type is a source contact pad, and the controlled contact pad of the second type is a drain contact pad.

15. The method of claim 11,
wherein a total thickness of a stack of the first power chip and the carrier structure is larger than a thickness of the logic chip, and wherein a total thickness of a stack of the second power chip and the carrier structure is larger than a thickness of the logic chip.

16. The method of claim 11,
wherein the carrier structure comprises an electrically conductive first portion contacting the first power chip and an electrically conductive second portion contacting the second power chip, and optionally comprises an electrically conductive connecting portion connecting the first portion and the second portion.

17. The method of claim 11,
wherein the electrically conductive carrier structure has a thickness in a range from about 100 μm to about 300 μm.

18. The method of claim 11,
wherein the electrically conductive carrier structure comprises an extension overlapping the logic chip, wherein the extension is electrically isolated from the logic chip by the mold material.

19. The method of claim 11,
wherein the electrically conductive carrier comprises or consists of copper.

20. The method of claim 11,
wherein the currents between the controlled pads of the first power chip and the second power chip, respectively, are vertical currents through the power chip and the chip package;

21. The method of claim 11,
wherein the arranging the first power chip and/or the arranging the second power chip comprises gluing, soldering, diffusion soldering and/or sintering.

22. The method of claim 11, further comprising:
before the forming of the redistribution layer, arranging a structured dielectric layer over a side that is exposed by the removed temporary carrier.

23. The method of claim 11,
wherein the forming the redistribution layer comprises sputtering and/or electroplating.

24. The method of claim 11,
wherein the first power chip and the second power chip are connected in a half-bridge configuration.

25. A chip system, comprising:
at least one chip package of claim 1;
at least one further component of a group of further components, the group consisting of:
a processor;
a controller;
a cooling structure;
a power source;
wherein the chip system is configured as a converter or a full bridge.
